(19) United States
(12) Patent Application Publication
(10) Pub. No.: US 2016/0146854 A1
(43) Pub. Date: May 26, 2016

(54) DISPLAY CIRCUIT FOR POWER LOAD AND METHOD OF THE SAME

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventor: PENG ZHANG, Wuhan (CN)

(21) Appl. No.: 14/585,528

(22) Filed: Dec. 30, 2014

(30) Foreign Application Priority Data
Nov. 21, 2014 (CN) 201410671678.2

(51) Int. Cl. G01R 13/02

(52) U.S. Cl. CPC G01R 13/02

(57) ABSTRACT

The display circuit coupled to a power source includes a connecting terminal, a detection resistor, a sample circuit, a comparison circuit, and an indicator circuit. The detection resistor is connected between the power source and the connecting terminal. The sampling circuit is connected to the connecting terminal for sampling a load voltage of the connecting terminal and generating a sample voltage. The comparison circuit with a first preset voltage and a second preset voltage is configured to compare the sample voltage with each of the first preset voltage and the second preset voltage. When the sample voltage is greater than the first preset voltage, the indicator circuit responds with a first response. When the sample voltage is greater than the second preset voltage, the indicator circuit responds with a second response. The disclosure further discloses a method of the display circuit.

### FIELD

The subject matter herein generally relates to display circuits for power load and method of the same.

### BACKGROUND

Nowadays, more and more power sources are attached with indicators. The power sources can indicate whether the power sources are supplying power or not via the indicators.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the views.

FIG. 1 is a block diagram of an embodiment of a display circuit for power load.

FIG. 2 is a circuit diagram of the display circuit for power load of FIG. 1.

FIG. 3 is a flow chart of a method of the display circuit for power load in accordance with an embodiment.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein. It should be noded that references to “an” or “one” embodiment in this disclosure are not necessarily to the same embodiment, and such references can mean “at least one.”

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising” means “including, but not necessarily limited to”; it specifically indicates open-terminated inclusion or membership in a so-described combination, group, series and the like.

The present disclosure is described in relation to a display circuit for power load. The display circuit coupled to a power source for power load, includes a connecting terminal for connecting an electric device, a detection resistor, a sampling circuit, a comparison circuit, and an indicator circuit. The detection resistor is connected between the power source and the connecting terminal for detecting an output current of the power source. The sampling circuit is connected to the connecting terminal for sampling a load voltage of the connecting terminal and generating a sample voltage. The comparison circuit with a first preset voltage and a second preset voltage therein is configured to compare the sample voltage with each of the first preset voltage and the second preset voltage. When the sample voltage is greater than the first preset voltage, the indicator circuit responds with a first response. When the sample voltage is greater than the second preset voltage, the indicator circuit responds with a second response.

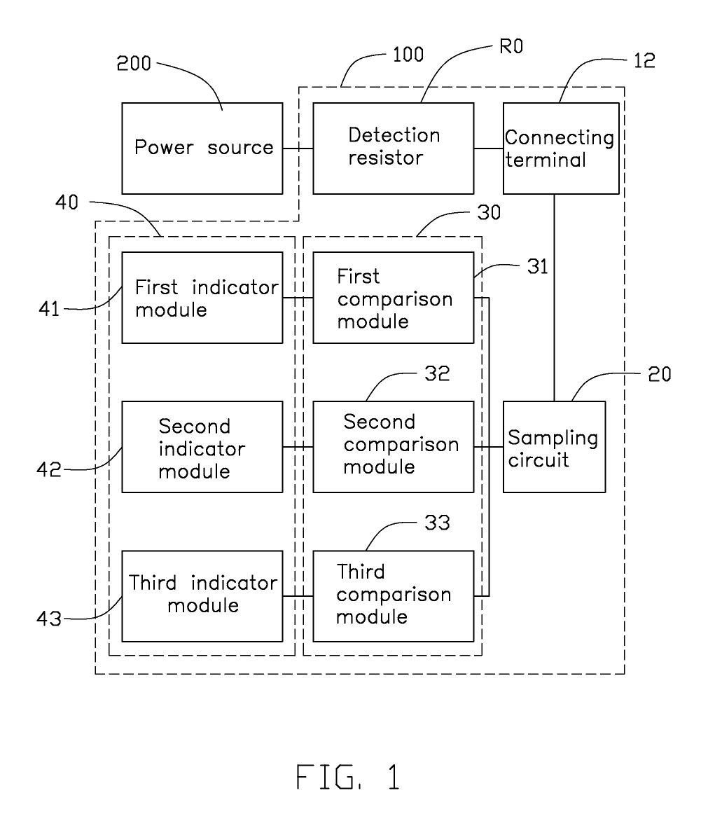

FIG. 1 illustrates an embodiment of a display circuit 100 connecting to a power source 200 for displaying a power load. The display circuit 100 includes a connecting terminal 12 for connecting an electric device (not shown), a detection resistor R0, a sampling circuit 20, a comparison circuit 30 setting a plurality of preset voltages, and an indicator circuit 40.

The detection resistor R0 is connected between the power source 200 and the connecting terminal 12 for detecting an output current of the power source 200. When the power load of the power source 200 is changed, the output current and a load voltage of the connecting terminal 12 are changed synchronously. In at least one embodiment, when the power load increases, the output currents increase synchronously.

In at least one embodiment, the detection resistor R0 is a precision resistor with tiny resistance.

The sampling circuit 20 coupled to the connecting terminal 12 is configured for sample the load voltage of the connecting terminal 12 and generating a sample voltage. The sample voltage is in direct proportion to the load voltage of the connecting terminal 12.

The comparison circuit 30 including a plurality of comparison modules is configured to compare the sample voltage with each of the preset voltages. The comparison circuit 30 is connected between the sampling circuit 20 and the indicator circuit 40. The indicator circuit 40 is controlled by the comparison circuit 30 to respond with different responses.

In at least one embodiment, the comparison circuit 30 includes a first preset voltage, a second preset voltage, and a third preset voltage. The first preset voltage is greater than the second preset voltage, and the second preset voltage is greater than the third preset voltage. The comparison circuit 30 further includes a first comparison module 31, a second comparison module 32, and a third comparison module 33. The first comparison module 31 is configured for comparing the sample voltage with the first preset voltage. The second comparison module 32 is configured for comparing the sample voltage with the second preset voltage. The third comparison module 33 is configured for comparing the sample voltage with the third preset voltage.

The indicator circuit 40 includes a plurality of indicator modules for the different responses. Each indicator module is coupled to each corresponding comparison module.

In at least one embodiment, the indicator circuit 40 includes a first indicator module 41 for a first response, a second indicator module 42 for a second response, and a third indicator module 43 for a third response. The first comparison module 31 is coupled to the first indicator module 41 and controls the first indicator module 41 to respond when the sample voltage is greater than the first preset voltage. The second comparison module 32 is coupled to the second indicator module 42 and controls the second indicator module 42 to respond when the sample voltage is greater than the second preset voltage. The third comparison module 33 is coupled to the third indicator module 43 and controls the third indicator module 43 to respond when the sample voltage is greater than the third preset voltage.

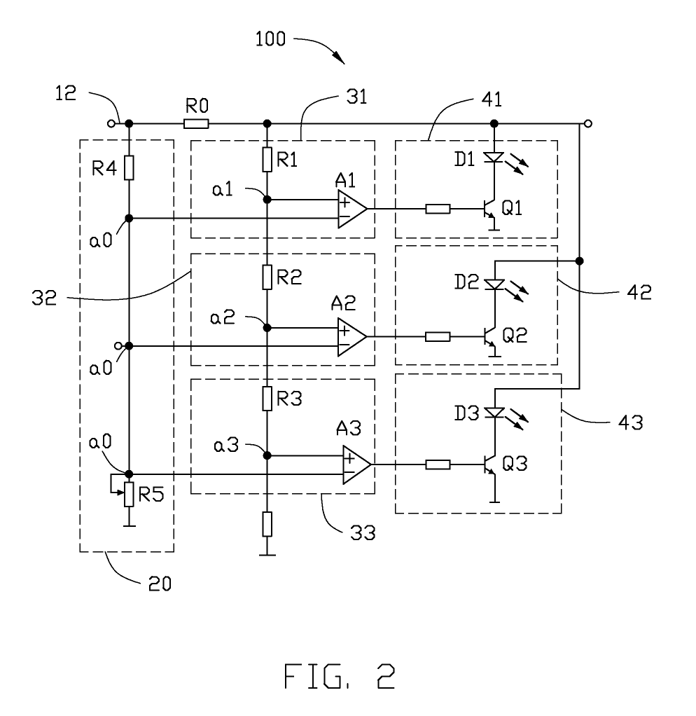

FIG. 2 illustrates that the sampling circuit 20 is coupled to the connected node of the detection resistor R0 and the connecting terminal 12. The sampling circuit 20 includes a fourth resistor R4 and a fifth resistor R5. A first terminal of the fourth resistor R4 is coupled to the connecting terminal 12, and a second terminal of the fourth resistor R4 is coupled to the fifth resistor R5 for forming a sampling node a0. In at least one embodiment, the fifth resistor R5 is an adjustable resistor, an electric potential of the sampling node a0 is adjustable according to the fifth resistor R5.

The first comparison module 31 includes a first resistor R1 and a first comparator A1. The second comparison module 32 includes a second resistor R2 and a second comparator A2. The third comparison module 33 includes a third resistor R3 and a third comparator A3. A first terminal of the first resistor R1 is coupled to the power source 200 (not shown), and a second terminal of the first resistor R1 is coupled to a first terminal of the second resistor R2 for forming a first node a1. A second terminal of the second resistor R2 is coupled to a first terminal of the third resistor R3 for forming a second node a2. A second terminal of the third resistor R3 is coupled to a first terminal of a pull-down resistor R9 for forming a third node a3. An electric potential of the first node a1 is greater than an electric potential of the second node a2; and an electric potential of the second node a2 is greater than an electric potential of the third node a3.

The first node a1 is coupled to a non-inverting input terminal of the first comparator A1 for inputting the first preset voltage as a reference voltage of the first comparator A1. The second node a2 is coupled to a non-inverting input terminal of the second comparator A2 for inputting the second preset voltage as a reference voltage of the second comparator A2. The third node a3 is coupled to a non-inverting input terminal of the third comparator A3 for inputting the third preset voltage as a reference voltage of the third comparator A3. Thereby, an electric potential of the non-inverting input terminal of the first comparator A1 is greater that an electric potential of the non-inverting input terminal of the second comparator A2; and an electric potential of the non-inverting input terminal of the second comparator A2 is greater that an electric potential of the non-inverting input terminal of the third comparator A3.

Each of the inverting input terminals of the first comparator A1, the second comparator A2, and the third comparator A3 is coupled to the sampling node a0. Thereby, the sample voltage is input to the first comparator A1, the second comparator A2, and the third comparator A3.

Each indicator module (such as first indicator module 31) includes a switch (such as Q1) and a light-emitting component (such as Dl). The comparison circuit 30 is coupled to each switch to switch on/off the switch. Each switch is coupled to each light-emitting component to turn on/off the light-emitting component.

In at least one embodiment, each switch is an npn type transistor. Each light-emitting component is a light emitting diode (LED).

In the first indicator module 41, an output terminal of the first comparator A1 is coupled to a base of the transistor Q1, the power source 200 (not shown) is coupled to the collector of the transistor Q1 via the LED D1, and an emitter of the first comparator A1 is grounded. When the sample voltage is greater than the first preset voltage, the transistor Q1 is switched on by the first comparator A1, and the LED D1 is turn on by the transistor Q1. Thereby, the first indicator module 41 is controlled to respond to the first response.

The relations of each element and working principle of the second indicator module 42 and the third indicator module 43 are similar to the first indicator module 41. Thereby, when the sample voltage is greater than the second preset voltage, the second indicator module 42 is controlled to respond to the second response; and when the sample voltage is greater than the third preset voltage, the third indicator module 43 is controlled to respond to the third response.

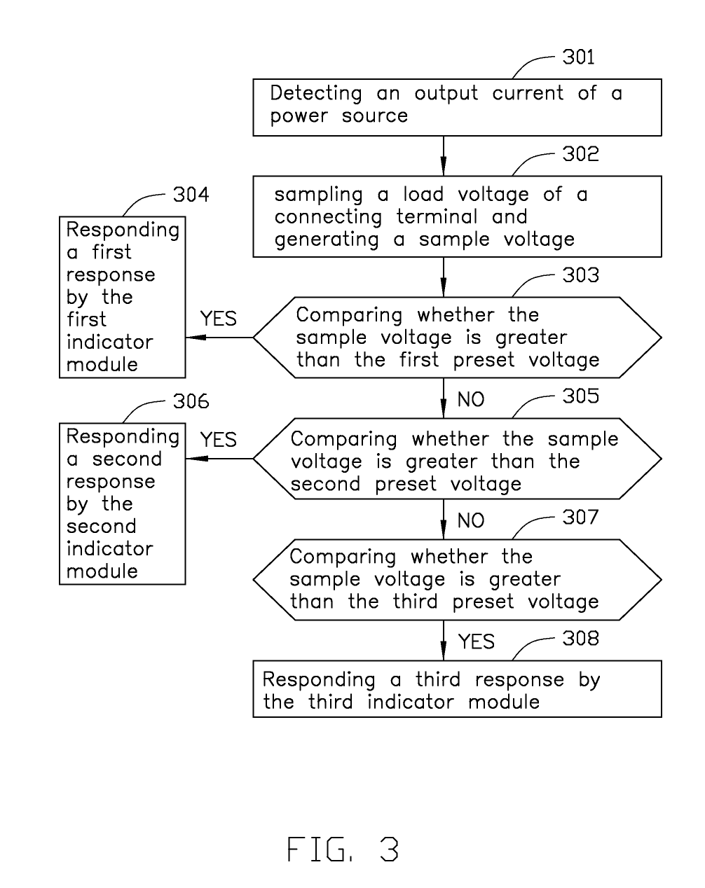

Referring to FIG. 3, a flowchart is presented in accordance with an example embodiment. The example method is provided by way of example, as there are a variety of ways to carry out the method. The method described below can be carried out using the configurations illustrated in FIGS. 1-2, for example, and various elements of these figures are referenced in explaining example method. Each block shown in FIG. 3 represents one or more processes, methods or subroutines, carried out in the example method. Furthermore, the illustrated order of blocks is illustrative only and the order of the blocks can change according to the present disclosure. Additional blocks can be added or fewer blocks may be utilized, without departing from this disclosure. The example method can begin at block 301.

At block 301: the detection resistor R0 detects the output current of a power source 200.

At block 302: the sampling circuit 20 samples the load voltage of the connecting terminal 12 and generates a sample voltage. The load voltage of the connecting terminal 12 is inversely proportional to the output current. Because the resistance of the detection resistor R0 is tiny, the value difference between the load voltage of the connecting terminal 12 and a load voltage of the power source 200 is also tiny.

At block 303: the first comparison module 31 compares the sample voltage with the first preset voltage; if the sample voltage is greater than the first preset voltage, go to block 304, if not, go to block 305.

At block 304: the first indicator module 41 responds to the first response.

At block 305: the second comparison module 32 compares the sample voltage with the second preset voltage; if the sample voltage is greater than the second preset voltage, go to block 306, if not, go to block 307.

At block 306: the second indicator module 42 responds to the second response.

At block 307: the third comparison module 33 compares the sample voltage with the third preset voltage; if the sample voltage is greater than the third preset voltage, go to block 308.

At block 308: the third indicator module 43 responds to the third response.

Block 303, block 305 and block 307 are able to be executed synchronously.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A display circuit for power load connected to a power source, the display circuit comprising:
a connecting terminal configured to connect to an electric device;
a detection resistor connected between the power source and the connecting terminal and configured to detect an output current of the power source;
a sampling circuit connected to the connecting terminal, the sampling circuit configured to sample a load voltage of the connecting terminal and generate a sample voltage;
a comparison circuit, configured to set a first preset voltage and a second preset voltage, and compare the sample voltage with each of the first preset voltage and the second preset voltage; and
an indicator circuit, configured to respond to the comparison circuit with a first response or a second response;
wherein the indicator circuit is configured such that when the sample voltage is greater than the first preset voltage, the indicator circuit responds with the first response; and the indicator circuit is configured such that when the sample voltage is greater than the second preset voltage, the indicator circuit responds with the second response.

2. The display circuit of claim 1, wherein the connected node of the detection resistor and the connecting terminal is coupled to the sampling circuit.

3. The display circuit of claim 1, wherein the first preset voltage is greater than the second preset voltage.

4. The display circuit of claim 3, wherein the comparison circuit comprises a first comparison module for comparing the sample voltage with the first preset voltage and a second comparison module for comparing the sample voltage with the second preset voltage.

5. The display circuit of claim 4, wherein the first comparison module comprises a first resistor, the second comparison module comprises a second resistor; a first terminal of the first resistor is coupled to the power source, and a second terminal of the first resistor is coupled to the second resistor.

6. The display circuit of claim 5, wherein the first comparison module further comprises a first comparator, a non-inverting input terminal of the first comparator is coupled to the first resistor, and an inverting input terminal of the first comparator is coupled to the sampling circuit.

7. The display circuit of claim 6, wherein the second comparison module further comprises a second comparator, a non-inverting input terminal of the second comparator is coupled to the second resistor, and an inverting input terminal of the second comparator is coupled to the sampling circuit.

8. The display circuit of claim 7, wherein a first terminal of the second resistor is coupled to the non-inverting input terminal of the first comparator; and a second terminal of the second resistor is coupled to the non-inverting input terminal of the second comparator.

9. The display circuit of claim 8, wherein an electric potential of the non-inverting input terminal of the first comparator is greater that an electric potential of the non-inverting input terminal of the second comparator.

10. The display circuit of claim 5, wherein the sampling circuit comprises a fourth resistor and a fifth resistor, a first terminal of the fourth resistor is coupled to the connecting terminal, and a second terminal of the fourth resistor is coupled to the fifth resistor.

11. The display circuit of claim 10, wherein the inverting input terminal of the first comparator is coupled to the second terminal of the fourth resistor.

12. The display circuit of claim 10, wherein the inverting input terminal of the second comparator is coupled to the second terminal of the fourth resistor.

13. The display circuit of claim 4, wherein the indicator circuit comprises two indicator modules for the first response and the second response.

14. The display circuit of claim 13, wherein the first comparison module is coupled to one of the indicator module, and the second comparison module is coupled to the other of the indicator module.

15. The display circuit of claim 13, wherein each indicator module comprises a switch and a light-emitting component, the comparison circuit is coupled to each switch to switch on/off the switch.

16. The display circuit of claim 15, wherein each switch is a transistor.

17. The display circuit of claim 15, wherein each switch is coupled to each light-emitting component to turn on/off the light-emitting component.

18. A method of a display circuit, comprising:
detecting an output current of a power source;
sampling a load voltage of a connecting terminal and generating a sample voltage;
comparing the sample voltage with each of a first preset voltage and a second preset voltage; and
responding with a first response or a second response.

19. The method of claim 18, further comprising responding with the first response when the sample voltage is greater than the first preset voltage; and responding with the second response when the sample voltage is greater than the second preset voltage.

20. The method of claim 18, wherein the first preset voltage is greater than the second preset voltage.
